(19) United States
(12) Patent Application Publication
(10) Pub. No.: US 2002/0190357 A1
(43) Pub. Date: Dec. 19, 2002

(54) Semiconductor circuit device and process for manufacturing the same

(75) Inventors: Ryuichi Kosugi, Tokyo (JP); Hideki Kawamura, Tokyo (JP)

Correspondence Address: MCDERMOTT, WILL & EMERY, 600 13th Street, N.W, Washington, DC, 20005-3096, US

(73) Assignee: Mitsubishi Denki Kabushiki Kaisha

(21) Appl. No.: 10/143,984

(22) Filed: May 14, 2002

(30) Foreign Application Priority Data
Jun. 15, 2001 (JP) P2001-181652

(51) Int. Cl. H01L 21/44; H01L 21/48; H01L 21/50; H01L 21/30; H01L 21/46; H01L 23/495; H01L 23/48; H01L 29/40

(52) U.S. Cl. 257/669; 438/113; 438/458; 257/620; 257/666; 257/674; 257/784

(57) ABSTRACT

A process for manufacturing a semiconductor circuit device includes the steps of forming a plurality of semiconductor chips (2) across dicing lines (3) on a wafer (1), dividing each chip from the wafer, die-bonding the chip onto a die-pad (11) of the lead-frame, connecting a pad electrode (12) of the chip and a terminal (14) of the lead-frame with a wire (15), and forming a resin seal (16) covering the connection between the pad electrode and the terminal. Then, the dicing line has a predetermined width for dividing each chip, and the dicing line includes a test element group (4) and an adjusting mark (5). Accordingly, in the step of forming the plurality of chips, a cross line (6) having no test element group and no adjusting mark is provided on the dicing line for connecting between the pad electrode and the terminal with the wire.

### BACKGROUND OF THE INVENTION

This invention relates to a semiconductor circuit device that has a semiconductor chip die-bonded on a lead-frame with wire.

Now, a small and thin semiconductor device is generally required. The manufacturing process for a semiconductor circuit device includes several processes as follows: FIG. 5A is a plane view that shows a plurality of semiconductor chips provided in regions bound by dicing lines 53 on a wafer 51, and FIG. 5B is a plane view that shows an enlarged plane view of a portion of FIG. 5A.

(1) The dicing lines 53, that are used for dividing each semiconductor chip 52 from a wafer on dicing process, are provided on the wafer 51. Both a test element group (TEG) 54 and an adjusting mark 55 for photolithography process are provided on the wafer 51 (FIG. 5B). Additionally, a plurality of semiconductor chips are provided in respective regions bound by the dicing lines 53 on the wafer 51 (FIG. 5A).

(2) Each semiconductor chip 52 is divided from the wafer 51.

(3) A semiconductor chip 52 is die-bonded on a die-pad of a lead-frame.

(4) A pad electrode 62 of the semiconductor chip 52 and a terminal 64 of the lead-frame are connected together with a wire 65.

(5) Finally, a seal 66 is provided on the semiconductor chip 52 by the use of a resin, so that connection between pad electrode 62 and the terminal 64 of the lead-frame can be protected with the terminal 64 exposed from the seal 66.

Consequently, the semiconductor device is provided. Notes that planing a back face of the semiconductor device and shortening the height of wire can result in reduction of the height of the package.

It is noted that there are a few prior arts relating to connection between a pad electrode of a semiconductor chip and a terminal of lead-frame. For example, the Japanese Laid-open Patent Publication No. 63-311731 shows a semiconductor device which has an insulator layer provided on the substrate of the device, for avoiding a shortcircuit between an edge of the substrate and a wire. The Japanese Laid-open Patent Publication No. 5-226406 shows a semiconductor device which has a chip having a plurality of pad electrodes and a lead-frame having a plurality of terminals. The coordinate of those pad electrodes may be different from each other, so that any packaging can be used. The Japanese Laid-open Patent Publication No. 2000-172733 shows a semiconductor device which has a bonding-pad located on a preferably area, so that the area efficiency can be increased.

In the process of manufacturing the semiconductor circuit device, the wafer 51 has dicing lines 53 having a predetermined width as a space, as shown in FIG. 5A. The dicing lines may have the test element group 54 for monitoring the characteristic of the semiconductor chip 52 and the adjusting mark 55 for photolithography, as shown in FIG. 5B. When the chip 52 is divided from the wafer 51, any scraps 67 from the test element group 54 or the adjusting mark 55 may remain on the chip 52. If any scraps will remain on the chip 52, when the pad electrode 62 of the chip 52 and the terminal 64 of lead-frame are connected together with wire 65, the scraps 67 may attach with the wire 65 to make a short-circuit, as shown FIG. 6 and FIG. 7. However, the wiring between the pad electrode 62 and the terminal 64 can be performed at a limited area because of miniaturizing and thinning of a package. If the height of wire 65 will be increased in order to prevent any connection between the scraps 67 and the wire 65, the wire will protrude from the seal 66 because the thickness of seal 66 is limited. Therefore, the wire may be forced from outside, and the reliability may thus be lost. Consequently, a short-circuit between the scraps 67 and the wire 65 may easily occur.

### SUMMARY OF THE INVENTION

Therefore, it is an object of the present invention to prevent a short-circuit between the pad electrode of the chip and the terminal of lead-frame.

In accordance with one aspect of the present invention, there is provided a process for manufacturing a semiconductor device including the steps of:

(1) forming a plurality of semiconductor chips in respective regions bound by dicing lines on a wafer;

(2) dividing each chip from the wafer;

(3) die-bonding the chip on a die-pad of the lead-frame;

(4) connecting a pad electrode of the chip with a terminal of the lead-frame by means of a wire; and

(5) forming a seal covering the connection between the pad electrode and the terminal on the chip by means of a resin.

More specifically, the dicing line has a predetermined width for dividing each chip from the wafer, and the dicing line includes a test element group and a adjusting mark. Additionally, in the step of forming the plurality of semiconductor chips, a cross line having no test element group and no adjusting mark is provided on the dicing line for connecting between the pad electrode and the terminal with the wire.

According to the semiconductor device of this invention, the dicing line has cross lines for wire-bonding between a pad electrode of the chip and a terminal of the lead-frame. The cross lines have no test element group and no adjusting mark. Consequently, when the chip is divided from a wafer, no scrap from the test element group or the adjusting mark exists on the cross lines. Therefore, the wire can extend between the pad electrode of the chip and the terminal of the lead-frame across the cross line without any scraps, so that a short-circuit between the scraps and the wire can be prevented. Moreover, the height of the wire can be decreased without the short-circuit with the scrap on the chip and the wire. Therefore, the height of the package can be decreased. Moreover, the wire can expose hardly out of the seal, so that the reliability of the semiconductor device may be increased.

In the step of forming the plurality of semiconductor chips, preferably, the cross line having no test element group and no adjusting mark may extend perpendicularly to the sideline of the chip. More preferably, the wire may extend perpendicularly to the sideline of the chip.

Consequently, due to the wire extending perpendicularly to the sideline of the chip, the area of the cross line can be decreased. Reducing the area of the cross line that has no test element group and no adjusting mark can result in increase of the area of test element group and adjusting mark, so that the area of all dicing line can be used effectively.

In another aspect of the present invention, there is provided a semiconductor device includes a lead-frame and a semiconductor chip having a part of dicing line remaining around the chip after dividing the chip from the wafer die-bonded on a die-pad of the lead-frame. Specifically, a cross line having no test element group and no adjusting mark is provided on the dicing line for connecting between the pad electrode and the terminal with the wire.

According to the semiconductor device of this invention, the cross line for connection between the pad electrode and the terminal is provided on the dicing line remaining around the chip. The dicing line is a part of the dicing line remaining after dividing the chip from the wafer. Moreover, the cross lines have no test element group and no adjusting mark. The pad electrode and the terminal are connected together across the cross line by means of the wire. When the chip is divided from a wafer, no scrap from the test element group and no scrap from the adjusting mark exist on the cross line. Therefore, the wire can extend between the pad electrode and the terminal across the cross line without any scraps, so that a short-circuit between the scraps and the wire can be prevented. Moreover, the height of the wire can be decreased without the short-circuit with the scrap on the chip and the wire. Therefore, the height of the package can be decreased. The wire can expose hardly out of the seal, so that the reliability of the semiconductor device may be increased.

### BRIEF DESCRIPTION OF THE DRAWINGS

FIG. 1A is a plane view of a wafer in the process for manufacturing a semiconductor device of a first embodiment of the invention;

FIG. 1B is an enlarged plane view of FIG. 1A;

FIG. 2 is a plane view of a semiconductor chip divided from a wafer on the process for manufacturing a semiconductor device of the first embodiment of the invention;

FIG. 3 is a partially plane view of a semiconductor device of the first embodiment of the invention;

FIG. 4 is a partially plane view of a semiconductor device of a second embodiment of the invention;

FIG. 5A is a plane view of a wafer on the process for manufacturing prior semiconductor device;

FIG. 5B is an enlarged view of a semiconductor chip;

FIG. 6 is a partially plane view of prior semiconductor device; and

FIG. 7 is a sectional view of FIG. 6 along a line A-B.

### DETAILED DESCRIPTION OF THE PREFERRED EMBODIMENTS

The semiconductor device according to embodiments of the present invention will be described below by using the accompanying drawings to make it easy to understand the invention. The same reference numerals as in the accompanying drawings denote the same parts in the accompanying drawings. The semiconductor device has a lead-frame and a semiconductor chip die-bonded on a die-pad of the lead-frame. The chip has a part of dicing lines remaining around the chip at the time of dividing the chip from the wafer. The dicing line has cross lines for wire-bonding between a pad electrode of the chip and a terminal of the lead-frame. The cross lines have no test element group and no adjusting mark. Consequently, when the chip is divided from a wafer, no scrap from the test element group or the adjusting mark exists on the cross lines. Therefore, the wire can extend between the pad electrode of the chip and the terminal of the lead-frame across the cross line without any scraps, so that a short-circuit between the scraps and the wire can be prevented.

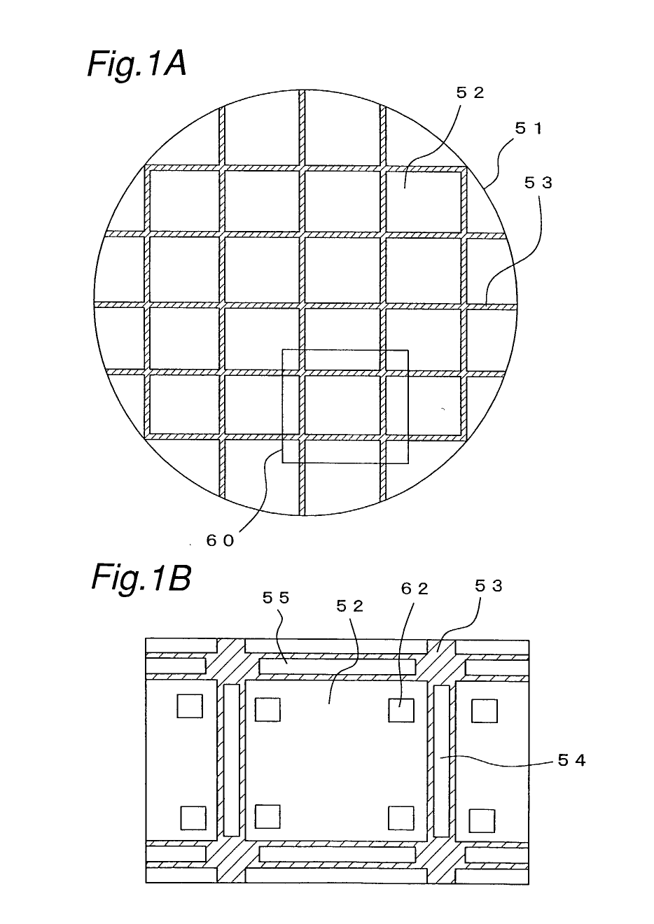

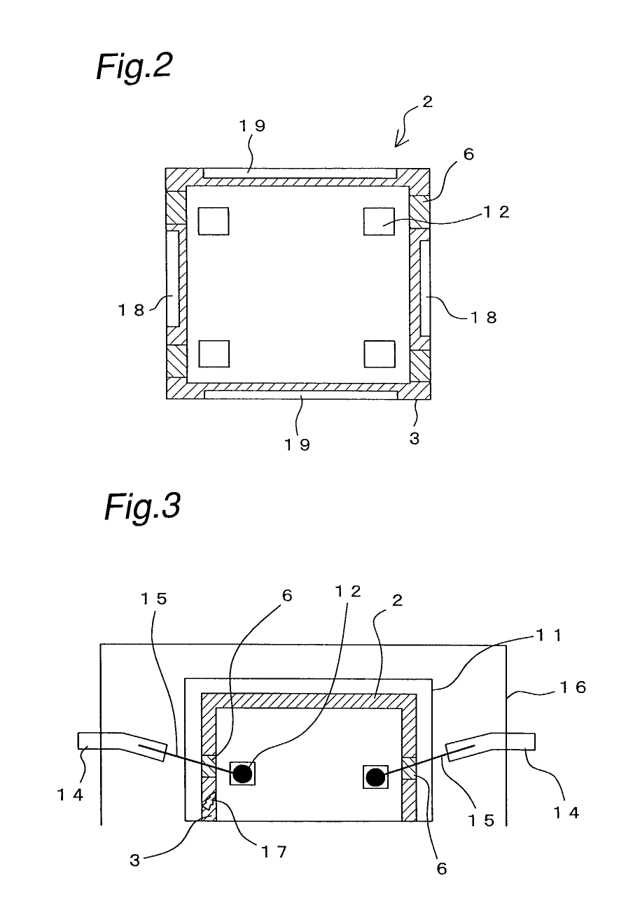

The semiconductor device has a semiconductor chip 2 having a part of dicing lines 3 remaining around the chip 2 after dividing the chip 2 from the wafer 1 as shown in FIG. 1A, FIG. 1B and FIG. 2. FIG. 1A is a plane view of a wafer 1 a having plurality of semiconductor chips 2 provided across the dicing lines 3. FIG. 1B is an enlarged plane view of FIG. 1A. FIG. 2 is a plane view of the semiconductor chip 2 divided from the wafer 1. The remaining dicing line includes several cross lines 6 for wire-bonding, many vestiges 18 of test element group 4, and many vestiges 19 of the adjusting mark 5, as shown in FIG. 2. The vestiges 18 of test element group 4 and the vestiges 19 of the adjusting mark 5 are made by dividing the chip 2 from the wafer 1. The pad electrode 12 of the chip and the terminal 14 of the lead-frame are connected together across the cross line 6 by means of wires, as shown in FIG. 3. When the chip 2 is divided from the wafer 1, the scrap 17 may be made by dividing the chip 2 from the wafer 1. The scrap 17 may remain around the vestige 18 of the test element group 4 and the vestige 19 of the adjusting mark 5. According to this embodiment of the present invention, the cross lines 6 that have no vestige of the test element group 4 and no vestige of the adjusting mark 5 is provided on the dicing line 3. Additionally, the wire 15 extends across the cross line 6 without any connection to the scrap 17. Consequently, the short-circuit with the wire 14 and the scrap 17 can be prevented.

The method of manufacturing the semiconductor device of this embodiment of the present invention preferably includes the following steps:

(1) A plurality of semiconductor chips 2 provided across dicing lines 3 having a predetermined width for dividing each chip on the wafer 1 (FIG. 1A). The test element group (TEG) 4 and the adjusting mark 5 for photolithography process are provided on the dicing lines 3 at the same time of providing the chips. Notes that the dicing line has a predetermined width as a margin for dividing each chip 2. on dicing process, are provided on the wafer 1. A cross line 6 that have no test element group 4 and no adjusting mark 5 is provided on the neighboring area providing a pad electrode on the dicing line 3 (FIG. 1B). The cross line will be used for connecting the pad electrode and the terminal together across the cross line by means of the wire in the following step (4).

(2) Each semiconductor chip 2 is divided from the wafer 1 by use of a dicer (not shown).

(3) A semiconductor chip 2 is die-bonded to a die-pad of a lead-frame.

(4) A pad electrode 12 of the semiconductor chip 2 and a terminal 14 of the lead-frame are connected together across the cross line 6 with a wire 15.

(5) Finally, a seal 16 is provided on the semiconductor chip 2 by the use of a resin, so that the connection between pad electrode 12 and the terminal 14 of the lead-frame can be protected from external environment, and the terminal 14 is partially exposed from the seal 16 in order to connect to external terminal (not shown).

According to the method of manufacturing the semiconductor device of this embodiment, the cross lines 6 having no test element group 4 and no adjusting mark 5 is provided on the dicing line 3. Therefore, there is no scrap on the cross line 6 where the wire extends. Consequently, the short-circuit with the scrap 17 and the wire 15 can be prevented. It is noted that the chip size of the semiconductor chip 2 and the location of the pad electrode 2 determine the form of the lead-frame. Additionally, which route of the wire 15 extending across the dicing line 3 can be estimated. The height of the wire 15 can be decreased without the short-circuit with the scrap 17 on the chip 2 and the wire 15. Therefore, the height of the package can be decreased. Moreover, the wire 15 can expose hardly out of the seal 16, so that the reliability of the semiconductor device may be increased.

The semiconductor device of a second embodiment of the present invention is characterized that the pad electrode and the terminal are connected together across the cross line neighboring perpendicularly to the sideline of rectangular chip with the wire. Consequently, the length of wire connecting the pad electrode and the terminal can be shortened. Additionally, the area of cross line can be decreased within the dicing line.

As compared with the semiconductor device of the first embodiment, the semiconductor device differs therefrom in that the pad electrode 12 and the terminal 14 are connected together across the cross line 6 neighboring perpendicularly to the sideline of rectangular chip 2 by means of the wire. Due to the wire 15 extending perpendicularly to the sideline of the chip 2, the area of the cross line can be decreased, as compared with the cross line tilting relative to the sideline. The cross line has no test element group and no adjusting mark. Shortening the area of the cross line, the area of test element group and adjusting mark can be increased, so that the area of all dicing line 3 can be used effectively. By the way, in the first embodiment, the wire 15 extends from the pad electrode 12 perpendicularly to the sideline of the rectangular chip 2 as shown in FIG. 3. When the wire is tilted relative to the sideline of the chip 2, the area of the cross line is larger than this embodiment. Additionally, the area of the test element group and the adjusting mark is smaller than this embodiment, so that the area of dicing line 3 can not be used effectively. Consequently, due to the semiconductor device of this embodiment, the area of the dicing line can be used effectively.

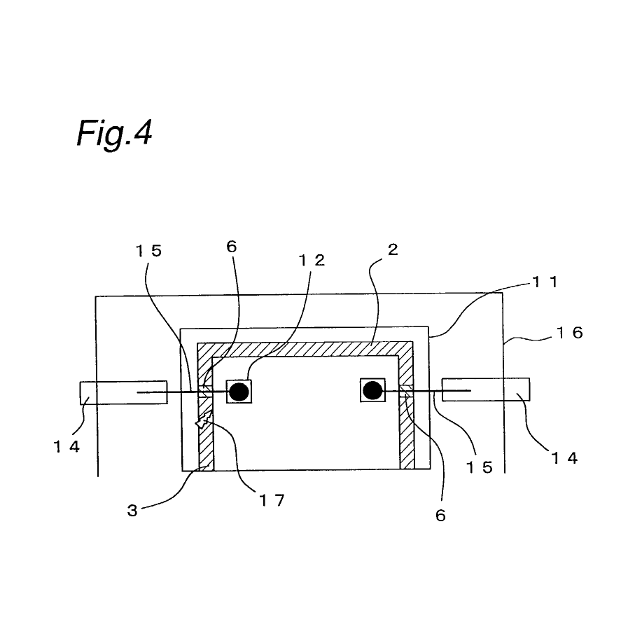

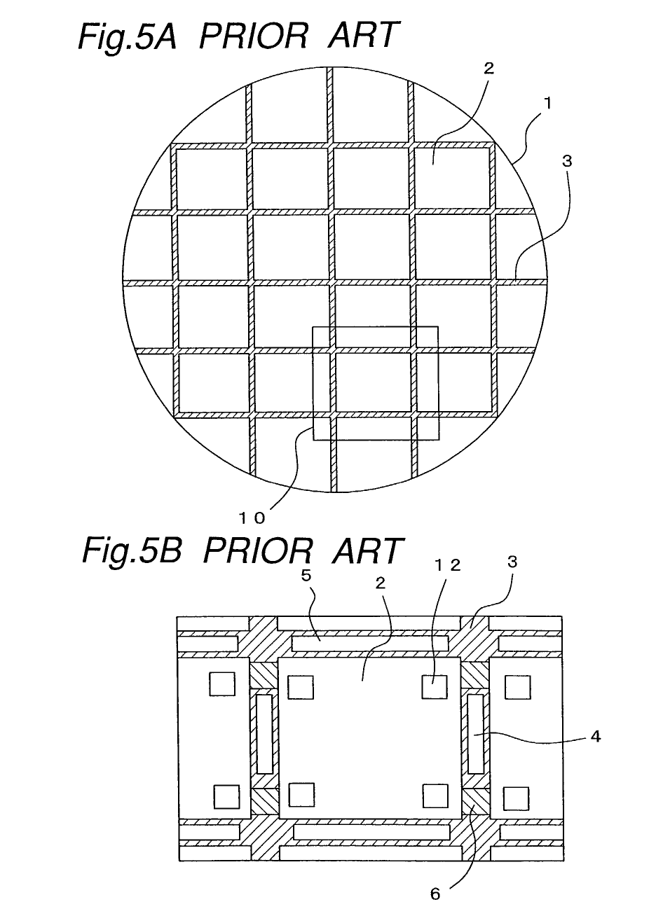

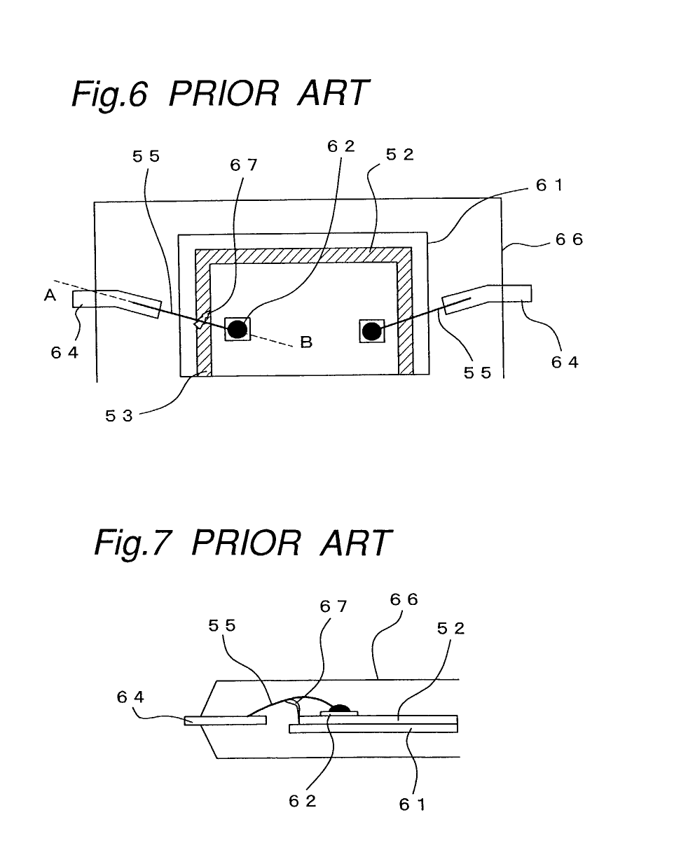

As compared with the first embodiment, the method of manufacturing the semiconductor device of this embodiment differs therefrom in the step of forming plurality of semiconductor chips, the area of the cross line 6 may be formed on neighboring perpendicularly to the sideline of the chip 2, as shown in FIG. 4. Additionally, the wire 15 extends perpendicularly to the side of the chip 2 from the pad electrode 12 to terminal 14 across the cross line 6. Therefore, the area of the cross line 6 can be decreased. Additionally, the length of the wire 15 can be shortened. Consequently, the area of the dicing line 3 can be used effectively.

What is claimed is:

1. A process for manufacturing a semiconductor device comprising the steps of:
forming a plurality of semiconductor chips across dicing lines on a wafer;
dividing each chip from the wafer;
die-bonding said chip onto a die-pad of the lead-frame;
connecting a pad electrode of the chip and a terminal of the lead-frame with a wire; and
forming a seal covering the connection between the pad electrode and the terminal on the chip by resin;
wherein the dicing line has a predetermined width for dividing each chip from the wafer, and the dicing line includes a test element group and an adjusting mark,
wherein in the step of forming the plurality of semiconductor chips, a cross line having no test element group and no adjusting mark is provided on the dicing line for connecting between the pad electrode and the terminal with the wire.

2. The process according to claim 1, wherein in the step of forming the plurality of semiconductor chips, the cross line having no test element group and no adjusting mark extends perpendicularly to the side of the chip.

3. A semiconductor device comprising:
a lead-frame; and
a semiconductor chip having a part of dicing line remaining around the chip after dividing the chip from the wafer die-bonded onto a die-pad of the lead-frame;
wherein a cross line having no test element group and no adjusting mark is provided on the dicing line for connecting between the pad electrode and the terminal with the wire.

4. The semiconductor device according to claim 3, wherein the pad electrode of the chip and the terminal of the lead-frame are connected across the cross line with the wire.
